(19) United States
(12) Patent Application Publication
(10) Pub. No.: US 2025/0087577 A1
(43) Pub. Date: Mar. 13, 2025

(54) Techniques For Providing Shielding Between Inductors Using Guard Rings

(71) Applicant: Altera Corporation, San Jose, CA (US)

(72) Inventor: Krishna Bharath Kolluru, Portland, OR (US)

(73) Assignee: Altera Corporation, San Jose, CA (US)

(21) Appl. No.: 18/956,735

(22) Filed: Nov. 22, 2024

(51) Int. Cl. H01L 23/522; H01L 21/768; H01L 23/00; H01L 23/498; H01L 25/16

(52) U.S. Cl. CPC H01L 23/5225; H01L 21/76877; H01L 23/49827; H01L 24/16; H10D 1/20; H01L 25/16; H01L 2224/16225

(57) ABSTRACT

An electronic interconnection device includes a guard ring that has a conductive region having a rectangular shape and a via filled with conductive material that is coupled to the conductive region. The guard ring is configured to provide shielding that reduces cross-coupling between inductors that are external to the electronic interconnection device. The via may extend to an external surface of the electronic interconnection device.

### BACKGROUND

Integrated circuits (ICs) are often housed in integrated circuit (IC) packages. An IC package contains conductors that couple an integrated circuit (IC) to conductive pads exposed on a surface of the IC package. The conductive pads on the surface of the IC package are typically coupled to a circuit board through conductive connections, such as conductive balls.

### BRIEF DESCRIPTION OF DRAWINGS

FIG. 1 is a diagram that illustrates a cross sectional view of an example of a circuit system that includes an integrated circuit (IC) die and an interposer.

FIG. 2 is a diagram that illustrates a tilted view of the first and the second guard rings of FIG. 1.

FIG. 3A is a diagram that illustrates a cross sectional view of an example of a circuit system that includes two integrated circuit (IC) dies and an interposer.

FIG. 3B is a diagram that illustrates a cross sectional view of an example of a circuit system that includes the two integrated circuit (IC) dies and an interposer having guard rings that each have three conductive regions.

FIG. 4 is a diagram that illustrates a top down view of an example of a conductive region in a guard ring in an interposer.

FIG. 5 is a diagram that illustrates an example of a configurable logic integrated circuit (IC).

FIG. 6A is a block diagram of a system that can be used to implement a circuit design to be programmed into a programmable logic device using design software.

FIG. 6B is a diagram that depicts an example of a programmable logic device that includes three fabric die and two base die that are connected to one another via microbumps.

FIG. 7 is a block diagram illustrating a computing system configured to implement one or more aspects of the embodiments disclosed herein.

### DETAILED DESCRIPTION

Cross-coupling between inductors can occur when the magnetic fields generated by one inductor induce a voltage in another inductor, causing unwanted interactions and degrading the performance of the other inductor. This phenomenon is particularly significant in high-frequency applications and in situations where inductors are closely spaced. Cross-coupling can occur between inductors in an electronic integrated circuit (IC) die and between inductors in two different electronic integrated circuit (IC) dies that are coupled to a passive interposer. The metal fill in a passive interposer can cause degradation of the inductance (L) and quality factor (Q) of inductors by increasing parasitic capacitance and mutual coupling across the inductors in same IC die or different IC dies.

According to some examples disclosed herein, grounded or floating guard rings having conductive regions (e.g., metal layers) and/or through-silicon vias (TSVs) filled with conductive material are provided in an interposer to reduce cross-coupling through the interposer between inductors in the same integrated circuit (IC) die or between inductors in different IC dies. The IC die or IC dies are coupled to the interposer.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the terms “connected” and “connection” mean a direct electrical connection between the circuits that are connected, without any intermediary devices. The terms “coupled” and “coupling” mean either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

This disclosure discusses integrated circuit devices, including configurable (programmable) integrated circuits, such as field programmable gate arrays (FPGAs) and programmable logic devices. As discussed herein, an integrated circuit (IC) can include hard logic and/or soft logic. The circuits in an integrated circuit device (e.g., in a configurable IC) that are configurable by an end user are referred to as “soft logic.” “Hard logic” generally refers to circuits in an integrated circuit device that have substantially less configurable features than soft logic or no configurable features.

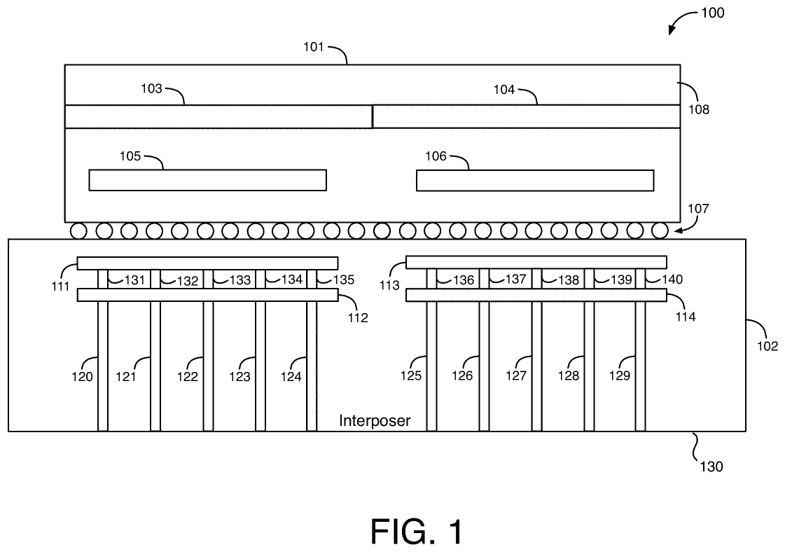

FIG. 1 is a diagram that illustrates a cross sectional view of an example of a circuit system 100 that includes an integrated circuit (IC) die 101 and an interposer 102. Interposer 102 can be an active or passive interposer. IC die 101 includes input/output circuits 103 and 104, inductors 105 and 106, front side metal 108, and additional circuits that are not shown in Figure (FIG. 1. IC die 101 is coupled to interposer 102 through conductive bumps 107. IC die 101 can be any type of integrated circuit, such as a configurable IC (e.g., a field programmable gate array (FPGA) or programmable logic device), a microprocessor IC, a graphics processing unit IC, a memory IC, an application specific IC, a transceiver IC, etc.

Interposer 102 includes 4 conductive regions 111, 112, 113, and 114, 10 vias 131-140 that are each filled with conductive material, and 10 through-silicon vias (TSVs) 120-129 that are each filled with conductive material. The conductive material in each of the TSVs 120, 121, 122, 123, and 124 is coupled to the conductive region 112. The conductive material in each of the TSVs 125, 126, 127, 128, and 129 is coupled to the conductive region 114. The conductive material in each of the vias 131-135 is coupled to each of the conductive regions 111 and 112. The conductive material in each of the vias 136-140 is coupled to each of the conductive regions 113 and 114. The conductive regions 111-114 and the conductive material in the vias and TSVs can, as examples, be metal or metal alloys.

The conductive material in each of vias 131-135 couples together conductive regions 111-112. The conductive material in each of the TSVs 120-124 extends from the conductive region 112 down to the bottom surface 130 of the interposer 102, as shown in FIG. 1. The conductive material in each of vias 136-140 couples together conductive regions 113-114. The conductive material in each of the TSVs 125-129 extends from the conductive region 114 down to the bottom surface 130 of the interposer 102, as shown in FIG. 1.

The conductive regions 111-112 and the conductive material in the vias 131-135 and through-silicon vias (TSVs) 120-124 are coupled together to form a first guard ring in interposer 102. The conductive regions 113-114 and the conductive material in the vias 136-140 and through-silicon vias (TSVs) 125-129 are coupled together to form a second guard ring in interposer 102. The first and the second guard rings are located below the inductors 105 and 106, respectively, as shown in FIG. 1. The first and second guard rings provide shielding that reduces cross-coupling through the interposer 102 between the inductors 105 and 106 within the same integrated circuit (IC) die 101. The first guard ring of FIG. 1 is not coupled to either of the inductors 105-106. The second guard ring of FIG. 1 is also not coupled to either of the inductors 105-106. The first and second guard rings can be grounded or floating. Although guard rings are disclosed herein as being in interposers, guard rings having the configurations disclosed herein can also be formed in other types of electronic interconnection devices.

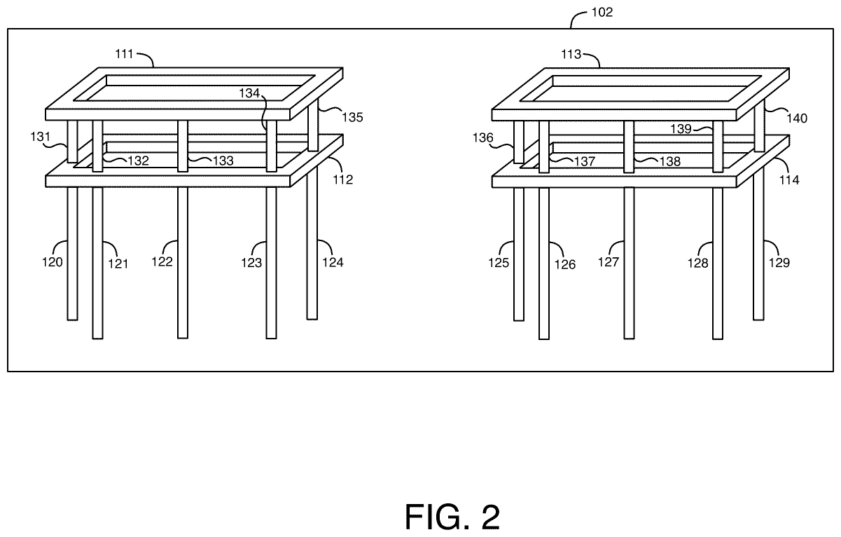

FIG. 2 is a diagram that illustrates a tilted view of the first and the second guard rings of FIG. 1 and that shows further details of the shapes of the conductive regions and the couplings between the conductive regions and the vias and TSVs. In the example of FIG. 2, each of the conductive regions 111, 112, 113, and 114 includes four linear conductors formed in one or more conductive layers of the interposer 102. A first two of the four linear conductors in each of the conductive regions 111-114 are parallel to each other, and the second two of the four linear conductors in each of the conductive regions 111-114 are parallel to each other. The four linear conductors in each of the conductive regions 111-114 are arranged and coupled together to form a rectangular shape. Thus, each of the conductive regions 111, 112, 113, and 114 is shaped as a rectangle when viewed from a top down perspective.

The conductive material in each of the vias 131-135 couples the rectangular conductive region 111 to the rectangular conductive region 112. The conductive material in each of TSVs 120-124 couples the rectangular conductive region 112 to the bottom surface of the interposer 102. The conductive material in each of the vias 136-140 couples the rectangular conductive region 113 to the rectangular conductive region 114. The conductive material in each of TSVs 125-129 couples the rectangular conductive region 114 to the bottom surface of the interposer 102.

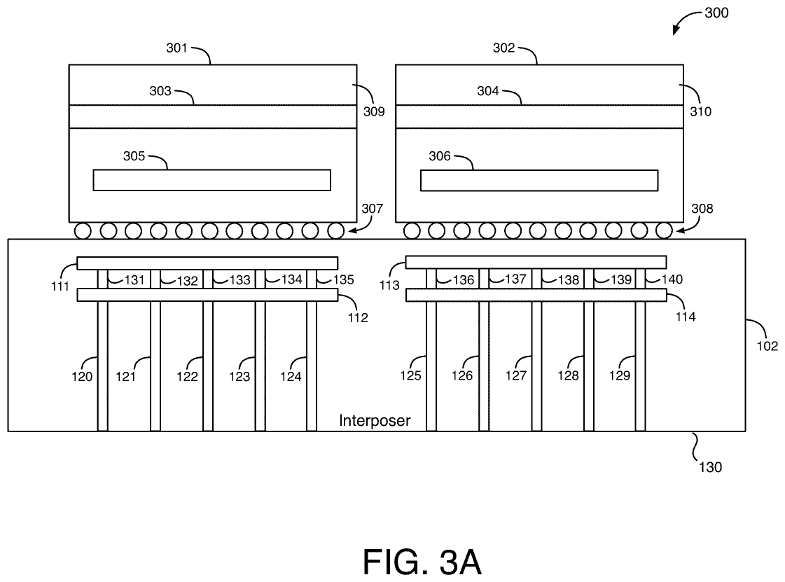

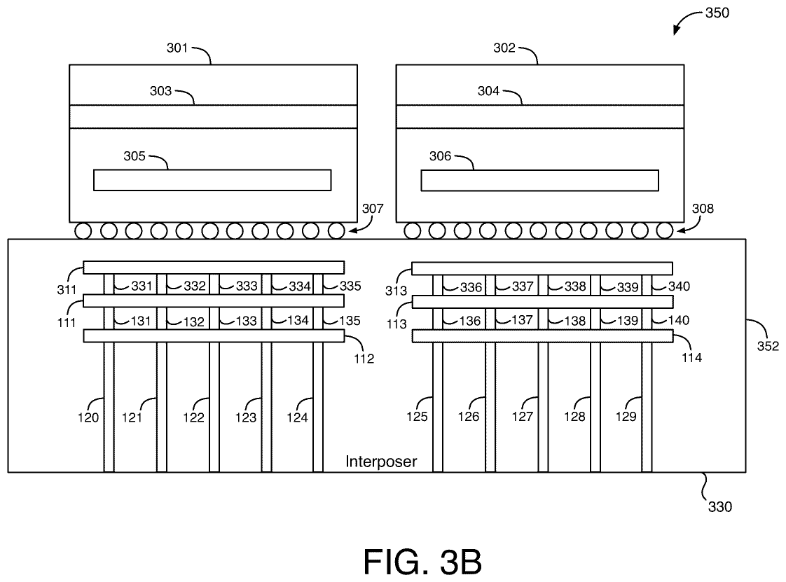

FIG. 3A is a diagram that illustrates a cross sectional view of an example of a circuit system 300 that includes two integrated circuit (IC) dies 301-302 and interposer 102. IC die 301 includes input/output circuitry 303, inductor 305, front side metal 309, and additional circuits that are not shown in FIG. 3A. IC die 302 includes input/output circuitry 304, inductor 306, front side metal 310, and additional circuits that are not shown in FIG. 3A. IC dies 301-302 are coupled to interposer 102 through conductive bumps 307-308, respectively. Interposer 102 is described above with respect to FIGS. 1-2. IC dies 301-302 can be any types of integrated circuits (ICs), such as configurable ICs, microprocessor ICs, graphics processing unit ICs, memory ICs, application specific ICs, transceiver ICs, or any combination thereof.

In the example of FIG. 3A, the first guard ring that includes conductive regions 111-112, the conductive material in vias 131-135, and the conductive material in TSVs 120-124 in the interposer 102 is located below inductor 305. Also, in the example of FIG. 3A, the second guard ring that includes conductive regions 113-114, the conductive material in vias 136-140, and the conductive material in TSVs 125-129 in the interposer 102 is located below inductor 306. The first and second guard rings provide shielding that reduces cross-coupling through the interposer 102 between the inductors 305 and 306 that are located in two different integrated circuit (IC) dies 301-302. The first guard ring of FIG. 3A is not coupled to either of the inductors 305-306, and the second guard ring of FIG. 3A is also not coupled to either of the inductors 305-306.

According to additional examples, guard rings in an interconnection device such as an interposer can have any number of conductive regions coupled to any number of vias and TSVs filled with conductive material. As another example, a guard ring in an interconnection device can have only one conductive region 111, 112, 113, or 114 that has a rectangular shape and is coupled to any number of TSVs filled with conductive material. As yet another example, a guard ring in an interconnection device can have three or more of the conductive regions 111-114 that each have a rectangular shape and are coupled to any number of vias and TSVs filled with conductive material.

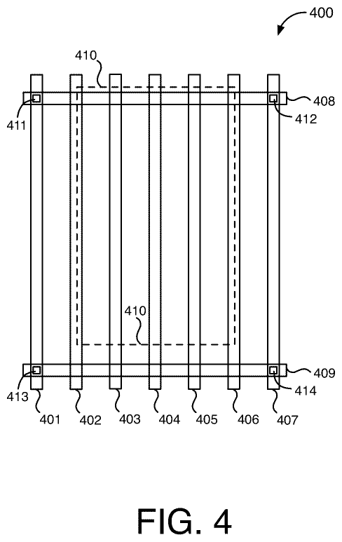

FIG. 3B is a diagram that illustrates a cross sectional view of an example of a circuit system 350 that includes the two integrated circuit (IC) dies 301-302 and an interposer 352 having guard rings that each have three conductive regions. The IC dies 301-302 are described above with respect to FIG. 3A. IC dies 301-302 are coupled to interposer 352 through conductive bumps 307-308, respectively. Interposer 352 includes 6 conductive regions 111, 112, 311, 113, 114, and 313, vias 131-140 and 331-340 that are each filled with conductive material, and the through-silicon vias (TSVs) 120-129 that are each filled with conductive material. Each of the additional conductive regions 311 and 313 can, for example, have conductors formed in a rectangular shape in one or more conductive layers of interposer 352, as disclosed herein with respect to FIGS. 2 and 4.

The conductive material in each of vias 331-335 couples together conductive regions 311 and 111. The conductive material in each of vias 131-135 couples together conductive regions 111-112. The conductive material in each of the TSVs 120, 121, 122, 123, and 124 is coupled to the conductive region 112. The conductive material in each of vias 336-340 couples together conductive regions 313 and 113. The conductive material in each of vias 136-140 couples together conductive regions 113-114. The conductive material in each of the TSVs 125, 126, 127, 128, and 129 is coupled to the conductive region 114. The conductive regions 111-114, 311, and 313 and the conductive material in the vias and TSVs can, as examples, include metal or metal alloys.

Each of the TSVs 120-124 extends from the conductive region 112 down to the bottom surface 330 of interposer 352. Each of the TSVs 125-129 extends from the conductive region 114 down to the bottom surface 330 of the interposer 352.

In the example of FIG. 3B, conductive regions 111-112 and 311, the conductive material in vias 331-335, and the conductive material in TSVs 120-124 are coupled together to form a first guard ring. The conductive regions 113-114 and 313, the conductive material in vias 336-340, and the conductive material in TSVs 125-129 are coupled together to form a second guard ring. The first and the second guard rings are located below the inductors 305 and 306, respectively, as shown in FIG. 3B. The first and second guard rings provide shielding that reduces cross-coupling through the interposer 352 between the inductors 305 and 306 within the IC dies 301-302. The first and second guard rings of FIG. 3B are not coupled to either of the inductors 305-306. The first and second guard rings of FIG. 3B can be grounded or floating.

FIG. 4 is a diagram that illustrates a top down view of an example of a conductive region 400 in a guard ring in an interposer. FIG. 4 shows 7 vertical conductors 401-407, two horizontal conductors 408-409, and four vias 411-414 filled with conductive material. The 7 conductors 401-407 are formed in a first conductive layer of the interposer, and the 2 conductors 408-409 are formed in a second conductive layer of the interposer. The interposer of FIG. 4 can be interposer 102, interposer 352, or another interposer.

The conductor 408 is coupled through the conductive material in each of vias 411-412 to conductors 401 and 407, respectively. The conductor 409 is coupled through the conductive material in each of vias 413-414 to conductors 401 and 407, respectively. Conductors 401, 407, 408, and 409 are coupled together through vias 411-414 to form a conductive region 400 that has a rectangular shape in the top down view of FIG. 4. Any one or more of the conductive regions 111, 112, 311, 113, 114, and 313 in any one or more of the guard rings disclosed herein with respect to FIGS. 1, 2, 3A, and 3B can have the structure of the conductive region 400 that is formed by conductors 401 and 407-409 and vias 411-414 as shown in detail in FIG. 4. The conductive region 400 formed by conductors 401 and 407-409 and vias 411-414 is located below an inductor 410 in an IC die. Inductor 410 can, as examples, be any of the inductors 105-106 or 305-306. The vertical conductors 402-406 are not coupled to, or part of, the conductive region 400 and are not coupled to any other part of the guard ring. Conductors 402-406 are merely added to conform to design rules for the interposer.

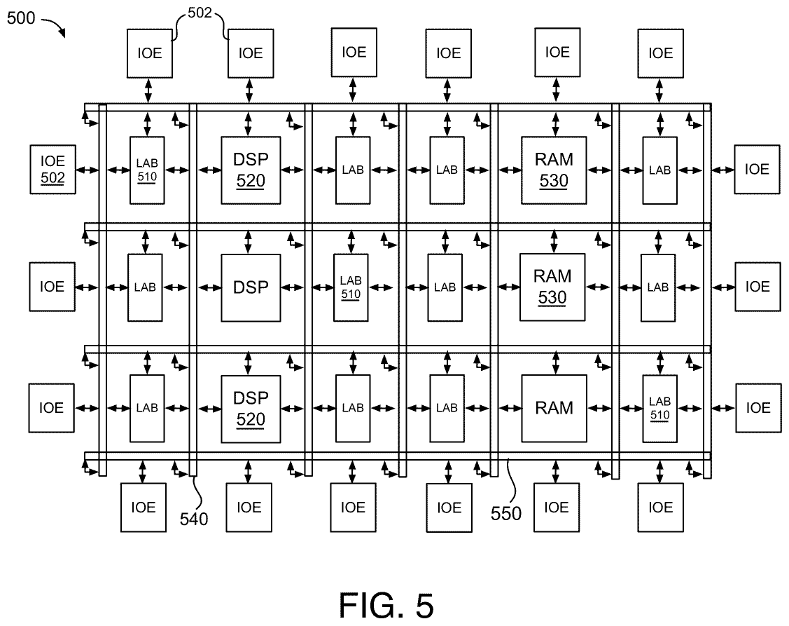

FIG. 5 illustrates an example of a configurable logic integrated circuit (IC) 500 that can include, for example, the circuitry disclosed herein with respect to any, some, or all of the IC dies of FIGS. 1, 2, 3A-3B, and/or 4. As shown in FIG. 5, the configurable logic integrated circuit (IC) 500 includes a two-dimensional array of configurable functional circuit blocks, including configurable logic array blocks (LABs) 510 and other functional circuit blocks, such as random access memory (RAM) blocks 530 and digital signal processing (DSP) blocks 520. Functional blocks such as LABs 510 can include smaller programmable logic circuits (e.g., logic elements, logic blocks, or adaptive logic modules) that receive input signals and perform custom functions on the input signals to produce output signals.

In addition, programmable logic IC 500 can have input/output elements (IOEs) 502 for driving signals off of programmable logic IC 500 and for receiving signals from other devices. Input/output elements 502 can include parallel input/output circuitry, serial data transceiver circuitry, differential receiver and transmitter circuitry, or other circuitry used to connect one integrated circuit to another integrated circuit. As shown, input/output elements 502 can be located around the periphery of the chip. If desired, the programmable logic IC 500 can have input/output elements 502 arranged in different ways. For example, input/output elements 502 can form one or more columns, rows, or islands of input/output elements that may be located anywhere on the programmable logic IC 500.

The programmable logic IC 500 can also include programmable interconnect circuitry in the form of vertical routing channels 540 (i.e., interconnects formed along a vertical axis of programmable logic IC 500) and horizontal routing channels 550 (i.e., interconnects formed along a horizontal axis of programmable logic IC 500), each routing channel including at least one conductor to route at least one signal.

Note that other routing topologies, besides the topology of the interconnect circuitry depicted in FIG. 5, may be used. For example, the routing topology can include wires that travel diagonally or that travel horizontally and vertically along different parts of their extent as well as wires that are perpendicular to the device plane in the case of three dimensional integrated circuits. The driver of a wire can be located at a different point than one end of a wire.

Furthermore, it should be understood that embodiments disclosed herein can be implemented in any integrated circuit or electronic system. If desired, the functional blocks of such an integrated circuit can be arranged in more levels or layers in which multiple functional blocks are interconnected to form still larger blocks. Other device arrangements can use functional blocks that are not arranged in rows and columns.

Programmable logic IC 500 can contain programmable memory elements. Memory elements can be loaded with configuration data using input/output elements (IOEs) 502. Once loaded, the memory elements each provide a corresponding static control signal that controls the operation of an associated configurable functional block (e.g., LABs 510, DSP blocks 520, RAM blocks 530, or input/output elements 502).

In a typical scenario, the outputs of the loaded memory elements are applied to the gates of metal-oxide-semiconductor field-effect transistors (MOSFETs) in a functional block to turn certain transistors on or off and thereby configure the logic in the functional block including the routing paths. Programmable logic circuit elements that can be controlled in this way include multiplexers (e.g., multiplexers used for forming routing paths in interconnect circuits), look-up tables, logic arrays, AND, OR, XOR, NAND, and NOR logic gates, pass gates, etc.

The programmable memory elements can be organized in a configuration memory array having rows and columns. A data register that spans across all columns and an address register that spans across all rows can receive configuration data. The configuration data can be shifted onto the data register. When the appropriate address register is asserted, the data register writes the configuration data to the configuration memory bits of the row that was designated by the address register.

In certain embodiments, programmable logic IC 500 can include configuration memory that is organized in sectors, whereby a sector can include the configuration RAM bits that specify the functions and/or interconnections of the subcomponents and wires in or crossing that sector. Each sector can include separate data and address registers.

The configurable logic IC of FIG. 5 is merely one example of an IC that can be used with embodiments disclosed herein. The embodiments disclosed herein can be used with any suitable integrated circuit or system. For example, the embodiments disclosed herein can be used with numerous types of devices such as processor integrated circuits, central processing units, memory integrated circuits, graphics processing unit integrated circuits, application specific standard products (ASSPs), application specific integrated circuits (ASICs), and programmable logic integrated circuits. Examples of programmable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

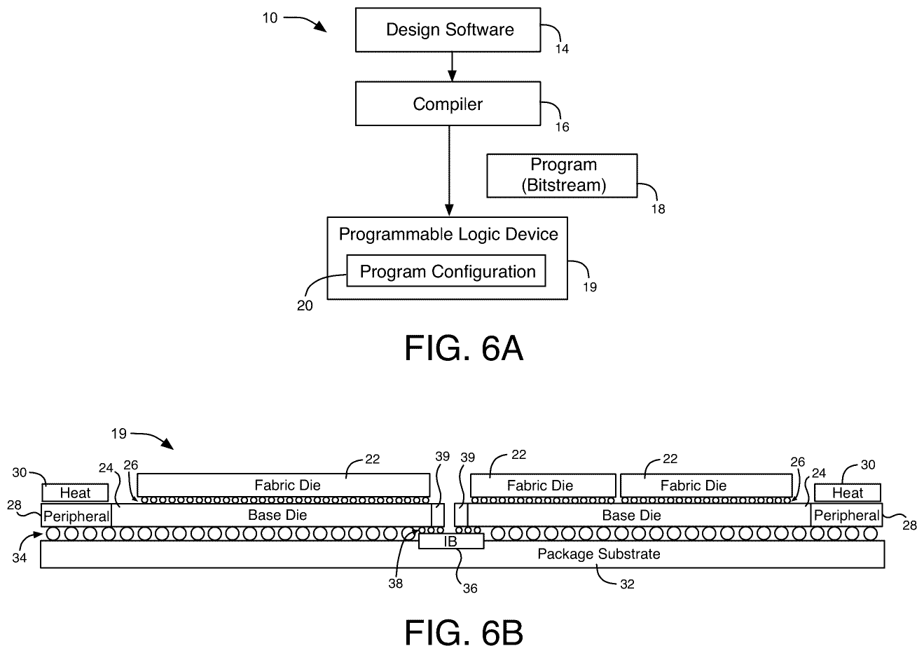

FIG. 6A illustrates a block diagram of a system 10 that can be used to implement a circuit design to be programmed into a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations that should be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or other highly specialized task.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 6B, but many others can be used, and it should be understood that this disclosure is intended to encompass any suitable programmable logic device where programmable logic fabric and fabric support circuitry are at least partially separated on different integrated circuit die.

FIG. 6B is a diagram that depicts an example of the programmable logic device 19 that includes three fabric die 22 and two base die 24 that are connected to one another via microbumps 26. In the example of FIG. 6B, at least some of the programmable logic fabric of the programmable logic device 19 is in the three fabric die 22, and at least some of the fabric support circuitry that operates the programmable logic fabric is in the two base die 24. For example, some of the circuitry of configurable IC 500 shown in FIG. 5 (e.g., LABs 510, DSP 520, and RAM 530) can be located in the fabric die 22 and some of the circuitry of IC 500 (e.g., input/output elements 502) can be located in the base die 24.

Although the fabric die 22 and base die 24 appear in a one-to-one relationship or a two-to-one relationship in FIG. 6B, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 19. The heat spreaders 30 can appear above, as pictured, and/or below the package (e.g., as a double-sided heat sink). The base die 24 can attach to a package substrate 32 via conductive bumps 34. In the example of FIG. 6B, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 19 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

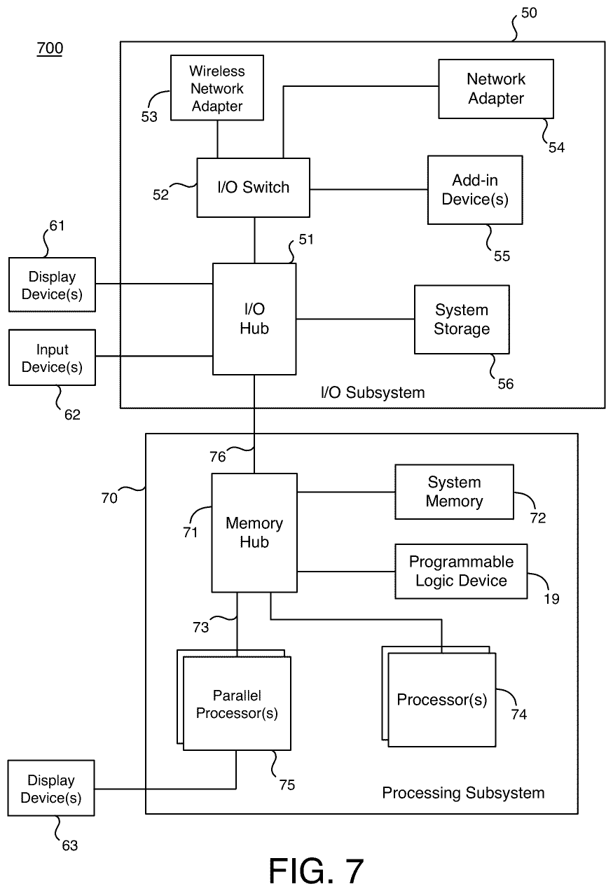

FIG. 7 is a block diagram illustrating a computing system 700 configured to implement one or more aspects of the embodiments described herein. The computing system 700 includes a processing subsystem 70 having one or more processor(s) 74, a system memory 72, and a programmable logic device 19 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 700 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 50, a system storage unit 56 can connect to the I/O hub 51 to provide a storage mechanism for the computing system 700. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 700 can include other components not shown in FIG. 7, including other port connections, optical storage drives, video capture devices, and the like, that can also be connected to the I/O hub 51. Communication paths interconnecting the various components in FIG. 7 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 700 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 700 can be integrated into a single package to form a system in package (SIP) configuration. In one embodiment, at least a portion of the components of the computing system 700 can be integrated into a multi-chip module (MCM), which can be interconnected with other multi-chip modules into a modular computing system.

The computing system 700 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 700. For example, any number of add-in cards or peripherals can be supported, or some components can be eliminated. Furthermore, some architectures can use different terminology for components similar to those illustrated in FIG. 7. For example, the memory hub 71 can be referred to as a Northbridge in some architectures, while the I/O hub 51 can be referred to as a Southbridge.

Additional examples are now described. Example 1 is an electronic interconnection device comprising: a first guard ring comprising a first conductive region having a first rectangular shape and a first via filled with first conductive material that is coupled to the first conductive region, wherein the first guard ring is configured to provide shielding that reduces cross-coupling between inductors that are external to the electronic interconnection device.

In Example 2, the electronic interconnection device of Example 1 may optionally include, wherein the first guard ring further comprises a second conductive region having a second rectangular shape that is coupled to the first conductive region through the first conductive material in the first via.

In Example 3, the electronic interconnection device of any one of Examples 1-2 may optionally include, wherein the first guard ring further comprises a second via filled with second conductive material that is coupled to the first conductive region.

In Example 4, the electronic interconnection device of any one of Examples 1-3 may optionally include, wherein the first guard ring further comprises a second conductive region having a second rectangular shape and a second via filled with second conductive material that is coupled to the first conductive region and to the second conductive region.

In Example 5, the electronic interconnection device of Example 4 may optionally include, wherein the first via and the second via extend from the first conductive region through the second conductive region to a surface of the electronic interconnection device.

In Example 6, the electronic interconnection device of any one of Examples 4-5 may optionally include, wherein the first guard ring further comprises a third conductive region having a third rectangular shape and a third via filled with third conductive material that is coupled to the first conductive region, to the second conductive region, and to the third conductive region.

In Example 7, the electronic interconnection device of any one of Examples 1-6 further comprises: a second guard ring comprising a second conductive region having a second rectangular shape and a second via filled with second conductive material that is coupled to the second conductive region, wherein the second guard ring is configured to provide shielding that reduces cross-coupling between the inductors.

In Example 8, the electronic interconnection device of Example 7 may optionally include, wherein the second guard ring further comprises a third conductive region having a third rectangular shape and a third via filled with third conductive material that is coupled to the second conductive region and to the third conductive region.

In Example 9, the electronic interconnection device of any one of Examples 1-8 may optionally include, wherein the electronic interconnection device is an interposer.

Example 10 is a method for reducing cross-coupling between inductors that are external to an electronic interconnection device, the method comprising: providing a first conductive region having a first rectangular shape in a first guard ring in the electronic interconnection device; and providing a first via filled with first conductive material in the first guard ring in the electronic interconnection device, wherein the first conductive material in the first via is coupled to the first conductive region.

In Example 11, the method of Example 10 further comprises: providing a second conductive region having a second rectangular shape in the first guard ring; and providing a second via filled with second conductive material in the first guard ring in the electronic interconnection device, wherein the second conductive material in the second via is coupled to the first conductive region and to the second conductive region.

In Example 12, the method of any one of Examples 10-11 further comprises: providing a second conductive region having a second rectangular shape in a second guard ring in the electronic interconnection device; and providing a second via filled with second conductive material in the second guard ring in the electronic interconnection device, wherein the second conductive material in the second via is coupled to the second conductive region.

In Example 13, the method of any one of Examples 11-12 may optionally include, wherein the first via and the second via extend to an external surface of the electronic interconnection device.

In Example 14, the method of any one of Examples 10-13 further comprises: providing a second conductive region formed in a second rectangular shape in the first guard ring, wherein the first conductive material in the first via is coupled to the second conductive region.

In Example 15, the method of any one of Examples 10-14 may optionally include, wherein the electronic interconnection device is an interposer.

Example 16 is a circuit system comprising: a first integrated circuit die comprising a first inductor; and an interposer coupled to the first integrated circuit die, wherein the interposer comprises a first guard ring, wherein the first guard ring comprises a first rectangular conductive region formed in at least a first conductive layer of the interposer, wherein the first guard ring further comprises a first via filled with first conductive material that is coupled to the first rectangular conductive region, and wherein the first guard ring provides shielding between the first inductor and a second inductor.

In Example 17, the circuit system of Example 16 may optionally include, wherein the first guard ring further comprises a second rectangular conductive region formed in at least a second conductive layer of the interposer, and wherein the first guard ring further comprises a second via filled with second conductive material that is coupled to the first rectangular conductive region and to the second rectangular conductive region.

In Example 18, the circuit system of any one of Examples 16-17 may optionally include, wherein the interposer further comprises a second guard ring comprising a second rectangular conductive region, wherein the second guard ring further comprises a second via filled with second conductive material that is coupled to the second rectangular conductive region, and wherein the second guard ring provides shielding between the first inductor and the second inductor.

In Example 19, the circuit system of any one of Examples 16-18 further comprises: a second integrated circuit die coupled to the interposer, wherein the second integrated circuit die comprises the second inductor.

In Example 20, the circuit system of any one of Examples 16-18 may optionally include, wherein the first integrated circuit die comprises the second inductor.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

What is claimed is:

1. An electronic interconnection device comprising:
a first guard ring comprising a first conductive region having a first rectangular shape and a first via filled with first conductive material that is coupled to the first conductive region, wherein the first guard ring is configured to provide shielding that reduces cross-coupling between inductors that are external to the electronic interconnection device.

2. The electronic interconnection device of claim 1, wherein the first guard ring further comprises a second conductive region having a second rectangular shape that is coupled to the first conductive region through the first conductive material in the first via.

3. The electronic interconnection device of claim 1, wherein the first guard ring further comprises a second via filled with second conductive material that is coupled to the first conductive region.

4. The electronic interconnection device of claim 1, wherein the first guard ring further comprises a second conductive region having a second rectangular shape and a second via filled with second conductive material that is coupled to the first conductive region and to the second conductive region.

5. The electronic interconnection device of claim 4, wherein the first via and the second via extend from the first conductive region through the second conductive region to a surface of the electronic interconnection device.

6. The electronic interconnection device of claim 4, wherein the first guard ring further comprises a third conductive region having a third rectangular shape and a third via filled with third conductive material that is coupled to the first conductive region, to the second conductive region, and to the third conductive region.

7. The electronic interconnection device of claim 1 further comprising:
a second guard ring comprising a second conductive region having a second rectangular shape and a second via filled with second conductive material that is coupled to the second conductive region, wherein the second guard ring is configured to provide shielding that reduces cross-coupling between the inductors.

8. The electronic interconnection device of claim 7, wherein the second guard ring further comprises a third conductive region having a third rectangular shape and a third via filled with third conductive material that is coupled to the second conductive region and to the third conductive region.

9. The electronic interconnection device of claim 1, wherein the electronic interconnection device is an interposer.

10. A method for reducing cross-coupling between inductors that are external to an electronic interconnection device, the method comprising:
providing a first conductive region having a first rectangular shape in a first guard ring in the electronic interconnection device; and
providing a first via filled with first conductive material in the first guard ring in the electronic interconnection device, wherein the first conductive material in the first via is coupled to the first conductive region.

11. The method of claim 10 further comprising:
providing a second conductive region having a second rectangular shape in the first guard ring; and
providing a second via filled with second conductive material in the first guard ring in the electronic interconnection device, wherein the second conductive material in the second via is coupled to the first conductive region and to the second conductive region.

12. The method of claim 10 further comprising:
providing a second conductive region having a second rectangular shape in a second guard ring in the electronic interconnection device; and
providing a second via filled with second conductive material in the second guard ring in the electronic interconnection device, wherein the second conductive material in the second via is coupled to the second conductive region.

13. The method of claim 12, wherein the first via and the second via extend to an external surface of the electronic interconnection device.

14. The method of claim 10 further comprising:
providing a second conductive region formed in a second rectangular shape in the first guard ring in the electronic interconnection device, wherein the first conductive material in the first via is coupled to the second conductive region.

15. The method of claim 10, wherein the electronic interconnection device is an interposer.

16. A circuit system comprising:
a first integrated circuit die comprising a first inductor; and
an interposer coupled to the first integrated circuit die, wherein the interposer comprises a first guard ring, wherein the first guard ring comprises a first rectangular conductive region formed in at least a first conductive layer of the interposer, wherein the first guard ring further comprises a first via filled with first conductive material that is coupled to the first rectangular conductive region, and wherein the first guard ring provides shielding between the first inductor and a second inductor.

17. The circuit system of claim 16, wherein the first guard ring further comprises a second rectangular conductive region formed in at least a second conductive layer of the interposer, and wherein the first guard ring further comprises a second via filled with second conductive material that is coupled to the first rectangular conductive region and to the second rectangular conductive region.

18. The circuit system of claim 16, wherein the interposer further comprises a second guard ring comprising a second rectangular conductive region, wherein the second guard ring further comprises a second via filled with second conductive material that is coupled to the second rectangular conductive region, and wherein the second guard ring provides shielding between the first inductor and the second inductor.

19. The circuit system of claim 16 further comprising:
a second integrated circuit die coupled to the interposer, wherein the second integrated circuit die comprises the second inductor.

20. The circuit system of claim 16, wherein the first integrated circuit die comprises the second inductor.
